(19) United States
(12) Patent Application Publication
(10) Pub. No.: US 2010/0266762 A1
(43) Pub. Date: Oct. 21, 2010

(54) PROCESSES AND AN APPARATUS FOR MANUFACTURING HIGH PURITY POLYSILICON

(76) Inventors: Ben Fieselmann, Bridgewater, NJ (US); David Mixon, Port Murray, NJ (US); York Tsuo, Livingston, NJ (US)

Correspondence Address: GREENBERG TRAURIG, LLP, MET LIFE BUILDING, 200 PARK AVENUE, NEW YORK, NY, 10166, US

(21) Appl. No.: 12/763,754

(22) Filed: Apr. 20, 2010

Related U.S. Application Data
(60) Provisional application No. 61/170,962, filed on Apr. 20, 2009.
(60) Provisional application No. 61/170,983, filed on Apr. 20, 2009.

(51) Int. Cl. C23C 16/24; C23C 16/44

(52) U.S. Cl. 427/212

(57) ABSTRACT

In one embodiment, a method includes feeding at least one silicon source gas and polysilicon silicon seeds into a reaction zone; maintaining the at least one silicon source gas at a sufficient temperature and residence time within the reaction zone so that a reaction equilibrium of a thermal decomposition of the at least one silicon source gas is substantially reached within the reaction zone to produce an elemental silicon; wherein the decomposition of the at least one silicon source gas proceeds by the following chemical reaction: 4HSiCl₃←→Si+3SiCl₄+2H₂, wherein the sufficient temperature is a temperature range between about 600 degrees Celsius and about 1000 degrees Celsius; and c) maintaining a sufficient amount of the polysilicon silicon seeds in the reaction zone so as to result in the elemental silicon being deposited onto the polysilicon silicon seeds to produce coated particles.

### RELATED APPLICATIONS

This application claims the benefit of U.S. provisional application Ser. No. 61/170,962 filed Apr. 20, 2009, and entitled “FLUIDIZED BED REACTOR MADE OF SILICIDE-FORMING METAL ALLOY WITH OPTIONAL STEEL BOTTOM AND OPTIONAL INERT PACKAGING MATERIAL,” and U.S. provisional application Ser. No. 61/170,983 filed Apr. 20, 2009, and entitled “GAS QUENCHING SYSTEM FOR FLUIDIZED BED REACTOR,” which are hereby incorporated herein by reference in their entirety for all purposes.

### BACKGROUND OF THE INVENTION

A chemical vapor deposition (CVD) is a chemical process that is used to produce high-purity solid materials. In a typical CVD process, a substrate is exposed to one or more volatile precursors, which react and/or decompose on the substrate surface to produce the desired deposit. Frequently, volatile by-products are also produced, which are removed by gas flow through the reaction chamber. A process of reducing with hydrogen of trichlorosilane (SiHCl₃) is a CVD process, known as the Siemens process. The chemical reaction of the Siemens process is as follows:

SiHCl₃(g)+H₂→Si(s)+3HCl(g) (“g” stands for gas; and “s” stands for solid)

In the Siemens process, the chemical vapor deposition of elemental silicon takes place on silicon rods, so called thin rods. These rods are heated to more than 1000 C under a metal bell jar by means of electric current and are then exposed to a gas mixture consisting of hydrogen and a silicon source gas, for example trichlorosilane (TCS). As soon as the thin rods have grown to a certain diameter, the process has to be interrupted, i.e. only batch wise operation rather than continuous operation is possible.

### BRIEF SUMMARY OF THE INVENTION

In one embodiment, a method includes feeding at least one silicon source gas and polysilicon silicon seeds into a reaction zone; maintaining the at least one silicon source gas at a sufficient temperature and residence time within the reaction zone so that a reaction equilibrium of a thermal decomposition of the at least one silicon source gas is substantially reached within the reaction zone to produce an elemental silicon; wherein the decomposition of the at least one silicon source gas proceeds by the following chemical reaction: 4HSiCl₃←→Si+3SiCl₄+2H₂, wherein the sufficient temperature is a temperature range between about 600 degrees Celsius and about 1000 degrees Celsius; wherein the sufficient residence time is less than about 5 seconds, wherein the residence time is defined as a void volume divided by total gas flow at the sufficient temperature; and c) maintaining a sufficient amount of the polysilicon silicon seeds in the reaction zone so as to result in the elemental silicon being deposited onto the polysilicon silicon seeds to produce coated particles.

In one embodiment, the sufficient heat is in a range of 700-900 degrees Celsius.

In one embodiment, the sufficient heat is in a range of 750-850 degrees Celsius.

In one embodiment, the silicon seeds have a distribution of sizes of 500-4000 micron.

In one embodiment, the silicon seeds have a distribution of sizes of 1000-2000 micron.

In one embodiment, the silicon seeds have a distribution of sizes of 100-600 micron.

In one embodiment, a method includes a) feeding at least one silicon source gas into a reaction zone; b) maintaining the at least one silicon source gas at a sufficient temperature and residence time within the reaction zone so that a reaction equilibrium of decomposition of the at least one silicon source gas is substantially reached within the reaction zone to produce an elemental silicon; i) wherein the decomposition of the at least one silicon source gas proceeds by the following chemical reaction: 4HSiCl₃←→Si+3SiCl₄+2H₂, ii) wherein the sufficient temperature is a temperature range between about 600 degrees Celsius and about 1000 degrees Celsius; iii) wherein the sufficient residence time is less than about 5 seconds, wherein the residence time is defined as a void volume divided by total gas flow at the sufficient temperature; and c) producing amorphous silicon.

### BRIEF DESCRIPTION OF THE SEVERAL VIEWS OF THE DRAWINGS

The present invention will be further explained with reference to the attached drawings, wherein like structures are referred to by like numerals throughout the several views. The drawings shown are not necessarily to scale, with emphasis instead generally being placed upon illustrating the principles of the present invention.

FIG. 1 shows an embodiment of a process in accordance with the present invention

FIG. 2 depicts a schematic diagram of an apparatus demonstrating an embodiment of the present invention.

FIG. 3 depicts a schematic diagram of an apparatus demonstrating an embodiment of the present invention.

FIG. 4 depicts an apparatus demonstrating an embodiment of the present invention.

FIG. 5 depicts visual conditions of quartz tubes in accordance with some embodiments of the present invention.

FIG. 6 depicts a graph representing some embodiments of the present invention.

FIG. 7 depicts a graph representing some embodiments of the present invention.

FIG. 8 depicts a schematic diagram of an apparatus demonstrating an embodiment of the present invention.

FIG. 9 depicts a graph representing some embodiments of the present invention.

FIG. 10 depicts an example of silicon particles with a coating of deposited silicon which was produced according to some embodiments of the present invention.

FIG. 11 depicts an example of silicon seed particles utilized in some embodiments of the present invention.

FIG. 12 depicts an example of a surface of a silicon particle coated with deposited silicon in accordance with some embodiments of the present invention.

FIG. 13 depicts a cross-section of a silicon particle coated with deposited silicon in accordance with some embodiments of the present invention.

FIG. 14 depicts an example of a silicon particle coated with deposited silicon in accordance with some embodiments of the present invention.

FIG. 15 depicts another example of a silicon particle coated with deposited silicon in accordance with some embodiments of the present invention.

FIG. 16 depicts a graph representing some embodiments of the present invention.

FIG. 17 a schematic diagram of an embodiment of the present invention.

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed invention.

### DETAILED DESCRIPTION OF THE INVENTION

Examples of such applications for which the present invention may be used are processes for production/purification of polysilicon. The examples of the processes for production/purification of polysilicon serve illustrative purposes only and should not be deemed limiting.

In embodiments, highly pure polycrystalline silicon (“polysilicon”), typically more than 99% purity, is a starting material for the fabrication of electronic components and solar cells. In embodiments, polysilicon is obtained by thermal decomposition of a silicon source gas. Some embodiments of the present invention are utilized to obtain highly pure polycrystalline silicon as granules, hereinafter referred to as “silicon granules”, in fluidized bed reactors in the course of a continuous CVD process due to thermal decomposition of silicon bearing compounds. The fluidized bed reactors are often utilized, where solid surfaces are to be exposed extensively to a gaseous or vaporous compound. The fluidized bed of granules exposes a much greater area of silicon surface to the reacting gases than is possible with other methods of CVD or thermal decomposition. A silicon source gas, such as HSiCl₃, or SiCl₄, is utilized to perfuse a fluidized bed comprising polysilicon particles. These particles, as a result, grow in size to produce granular polysilicon.

For the purposes of describing the present invention, the following terms are defined:

“Silane” means: any gas with a silicon-hydrogen bond. Examples include, but are not limited to, SiH₄; SiH₂Cl₂; SiHCl₃.

“Silicon Source Gas” means: Any silicon-containing gas utilized in a process for production of polysilicon; in one embodiment, any silicon source gas capable of reacting with an electropositive material and/or a metal to form a silicide.

In an embodiment, a suitable silicon source gas includes, but not limited to, at least one HₓSi_{y}Cl_{z} compound, wherein x, y, and z is from 0 to 6.

“STC” means silicon tetrachloride (SiCl₄).

“TCS” means trichlorosilane (SiHCl₃).

The thermal decomposition is the separation or breakdown of a chemical compound into elements or simpler compounds at a certain temperature. The present invention is described with respect to the following overall chemical reaction of the thermal decomposition of silicon source gas:

Silicon Source Gas [symbol] Si+XSiClₙ+YH₂, wherein X and Y depends on the composition of the given silicon source gas, and n is between 2 and 4. In some embodiments, the silicon source gas is TCS, which is thermally decomposed according to the following reaction:

4HSiCl₃ [symbol] Si+3SiCl₄+2H₂ (1)

The above generalized reaction (1) is representative, but not limiting, of various other reactions that may take place in the environment that is defined by the various embodiments of the present invention. For example, the reaction (1) may represent an outcome of multi-reaction environment, having at least one intermediary compound which differs from a particular product shown by the reaction (1). In some other embodiments, molar ratios of the compounds in the reaction (1) vary from the representative ratios above but the ratios remain acceptable if the rate of depositing Si is not substantially impaired.

For the purposes of describing the present invention, the “reaction zone” is an area in a reactor which is designed so that the thermal decomposition reaction (1) primarily occurs within the reaction zone area.

In some embodiments, the decomposition reaction (1) is conducted at temperatures below 900 degrees Celsius. In some embodiments, the decomposition reaction (1) is conducted at temperatures below 1000 degrees Celsius. In some embodiments, the decomposition reaction (1) is conducted at temperatures below 800 degrees Celsius. In some embodiments, the decomposition reaction (1) is conducted at temperatures between 650 and 1000 degrees Celsius. In some embodiments, the decomposition reaction (1) is conducted at temperatures between 650 and 850 degrees Celsius. In some embodiments, the decomposition reaction (1) is conducted at temperatures between 650 and 800 degrees Celsius. In some embodiments, the decomposition reaction (1) is conducted at temperatures between below 700 and 900 degrees Celsius. In some embodiments, the decomposition reaction (1) is conducted at temperatures between below 700 and 800 degrees Celsius.

### EXAMPLES

Some embodiments of the present invention are characterized by the following examples of processes for continuous production of polysilicon, without being deemed a limitation in any manner thereof.

In some embodiments of the present invention, processes for continuous production of polysilicon form a closed-loop production cycle. In some embodiments, at a start of the polysilicon production, a hydrogenation unit converts silicon tetrachloride (STC) to trichlosilane (TCS) with hydrogen and metallurgical grade silicon (“Si(MG)”) using, for example, the following reaction (2):

3SiCl₄+2H₂+Si(MG) [symbol] 4HSiCl₃ (2)

In some embodiments, the TCS is separated by distillation from STC and other chlorosilanes and then purified in a distillation column. In some embodiments, the purified TCS is then decomposed to yield olysilicon by allowing silicon to deposit on seed silicon particles in a fluidized bed environment, resulting in a growth of granules of Si from the seed particles in accordance with the representative reaction (1) above.

In some embodiments, a distribution of sizes of the seed silicon particles varies from 50 micron (μm) to 2000 μm. In some embodiments, a distribution of sizes of the seed silicon particles varies from 100 μm to 1000 μm. In some embodiments, a distribution of sizes of the seed silicon particles varies from 25 μm to 145 μm. In some embodiments, a distribution of sizes of the seed silicon particles varies from 200 μm to 1500 μm. In some embodiments, a distribution of sizes of the seed silicon particles varies from 100 μm to 500 μm. In some embodiments, a distribution of sizes of the seed silicon particles varies from 150 μm to 750 μm. In some embodiments, a distribution of sizes of the seed silicon particles varies from 1050 μm to 2000 μm. In some embodiments, a distribution of sizes of the seed silicon particles varies from 600 μm to 1200 μm. In some embodiments, a distribution of sizes of the seed silicon particles varies from 500 μm to 2000 μm.

In some embodiments, the initial seed silicon particles grow bigger as TCS deposits silicon on them. In some embodiments, the coated particles are periodically removed as product. In some embodiments, a distribution of sizes of the granular silicon product varies from 250 μm to 4000 μm. In some embodiments, a distribution of sizes of the granular silicon product varies from 250 μm to 3000 μm. In some embodiments, a distribution of sizes of the granular silicon product varies from 1000 μm to 4000 μm. In some embodiments, a distribution of sizes of the granular silicon product varies from 3050 μm to 4000 μm. In some embodiments, a distribution of sizes of the granular silicon product varies from 500 μm to 2000 μm. In some embodiments, a distribution of sizes of the granular silicon product varies from 200 μm to 2000 μm. In some embodiments, a distribution of sizes of the granular silicon product varies from 1500 μm to 2500 μm. In some embodiments, a distribution of sizes of the granular silicon product varies from 250 μm to 4000 μm.

The STC formed during the decomposition reaction (1) is recycled back to through the hydrogenation unit in accordance with the representative reaction (2). In some embodiments, the recycling of the STC allows for a continuous, close-loop purification of Si(MG) to Polysilicon.

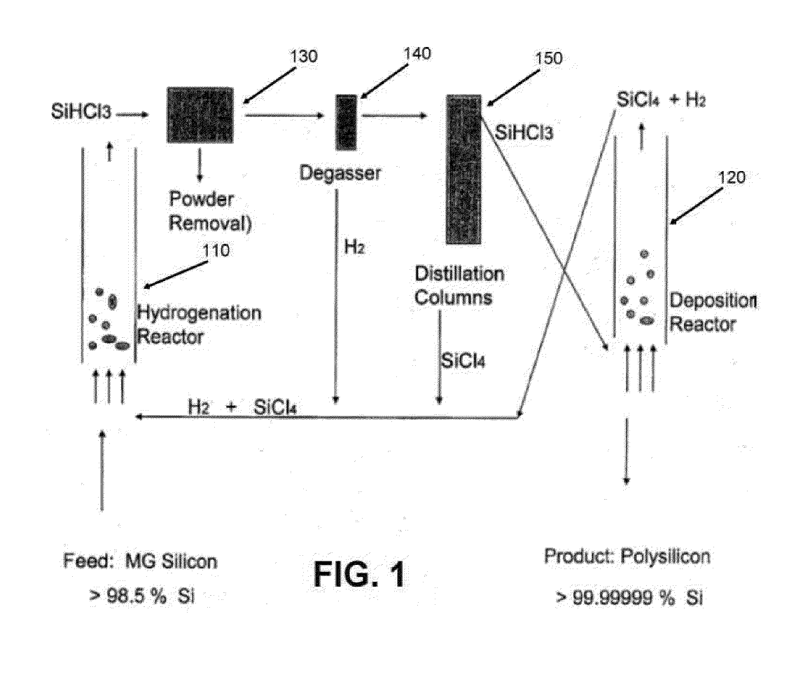

FIG. 1 shows an embodiment of a closed-loop, continuous process of producing polysilicon using the chemical vapor deposition of the TCS thermal decomposition that is generally described by the reactions (1) and (2) above. In one embodiment, metallurgical grade silicon is fed into a hydrogenation reactor 110 with sufficient proportions of TCS, STC and H₂ to generate TCS. TCS is then purified in a powder removal step 130, degasser step 140, and distillation step 150. The purified TCS is fed into a decomposition reactor 120, where TCS decomposes to deposit silicon on beads (silicon granules) of the fluidized bed reactor. The produced STC and H₂ are recycled back into the hydrogenation reactor 110.

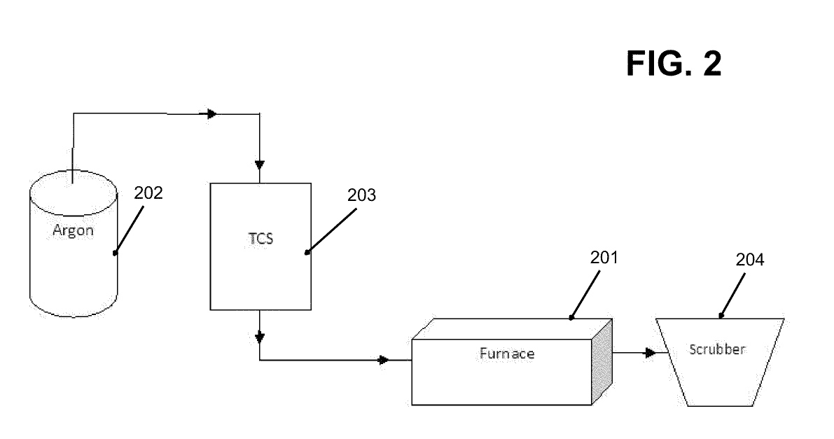

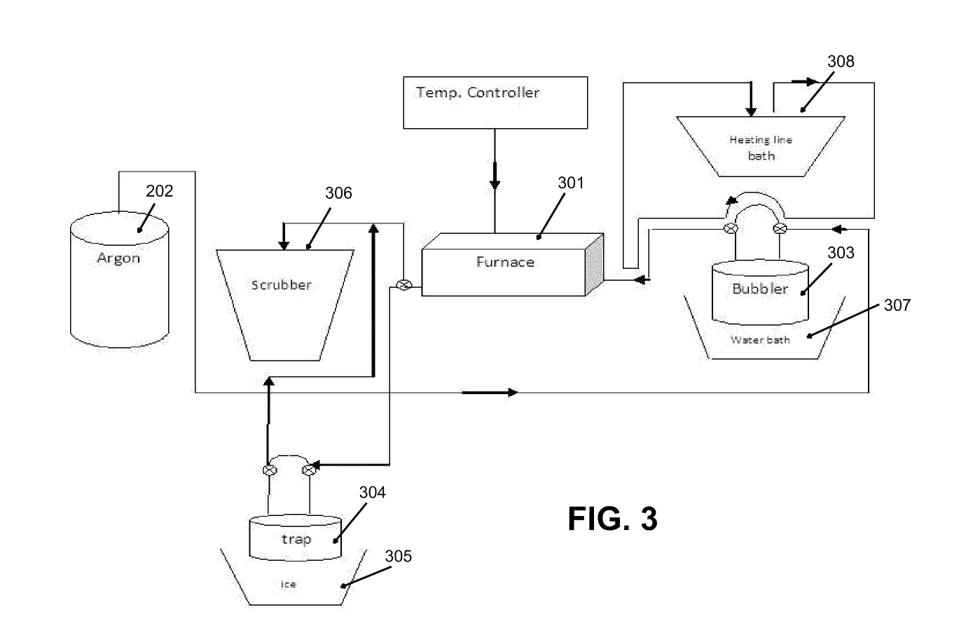

FIGS. 2 and 3 show an apparatus demonstrating some embodiments of the present invention. The apparatus was assembled using a single zone Thermcraft furnace (201, 301), for heat reactor tubes from 0.5 OD (outside diameter) to 3.0 inch OD. In some embodiments, tubes of a half inch (0.5 inch) OD were used. In some embodiments, tubes were filled with polysilicon seed particles with sizes that varied from 500 to 4000 μm.

In some embodiments, a stream of argon (from a reservoir 202, 302) was passed through a flow meter and then a bubbler (203, 303) with TCS. In some embodiments, the saturated stream was passed into a tube in the furnace (201, 301). In some embodiments, the reactor tubes were 14 mm OD quartz tubes with 10 mm ID (inside diameter) with 0.5 inch OD end fittings prepared by United Silica. In some embodiments, the ends of the tubes were ground to 0.5 inch OD and then connected to 0.5 inch UltraTorr® fittings from Swagelok® with Viton® o-rings. In some embodiments, quartz tubes were needed because the desired temperatures (500-900 degrees Celsius) exceed those that can be handled by ordinary borosilicate glass tubes.

Some embodiments of the present invention are based on an assumption that the representative reaction (1) of TCS decomposition is a first order reaction which goes through at least one intermediate compound, such as SiCl₂. The reasons and mathematical justifications for a basis of why, at least at some particular conditions, the TCS decomposition exhibits characteristics of first order reactions are disclosed in K. L. Walker, R. E. Jardine, M. A. Ring, and H. E. O'Neal, International Journal of Chemical Kinetics, Vol. 30, 69-88 (1998), whose disclosure is incorporated herein in its entirety for all purposes, including but not limiting to, providing the basis on which TCS decomposition is deemed to be the first order reaction and intermediate steps/products at least in some instances. In some embodiments, the rate determining step during TCS decomposition was the following intermediate reaction (3):

HSiCl₃→SiCl₂+HCl (3)

In some embodiments, the rate of the TCS decomposition reaction depends only on the concentration of TCS and the temperature. In some embodiments, once the SiCl₂ is formed, all the steps that follow to depositing elemental silicon proceed rapidly, as compare to a rate limiting step of the TCS thermal decomposition. In some embodiments, the formed HCl gets consumed and does not affect the reaction rate of the overall representative reaction (1). In some embodiments, when a reactor tube is packed with silicon particles, then the following reaction (4) occurs with the TCS undergoing chemical vapor deposition onto the granular silicon particles:

4HSiCl₃+Si (Poly-Si Particles) Si—Si(Poly-Si Particles)+3SiCl₄+2H₂ (4)

In some embodiments, if the tube is empty, then amorphous silicon powder is formed in the free space as follows:

8HSiCl₃→Si—Si (powder)+6SiCl₄+4H₂ (5)

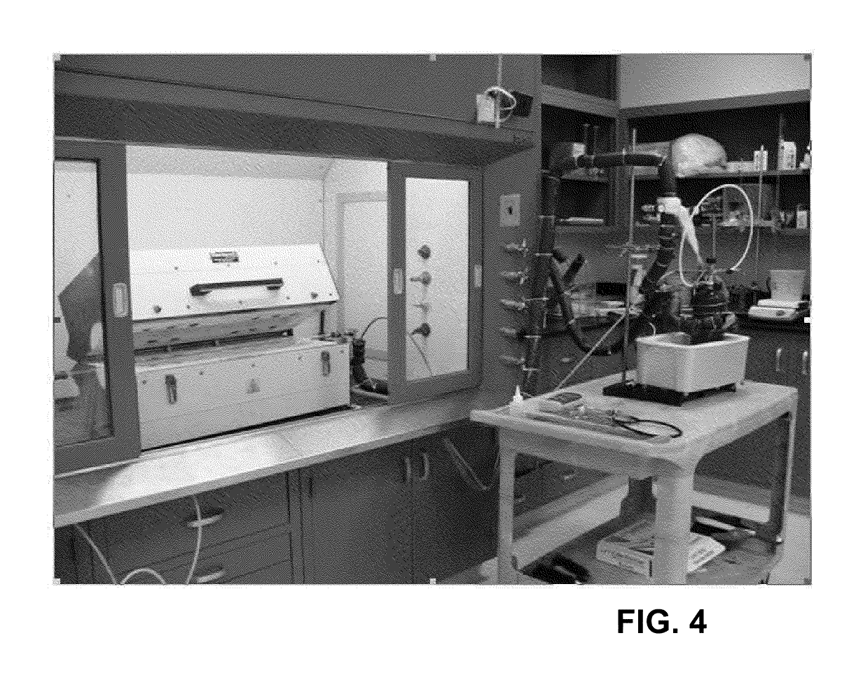

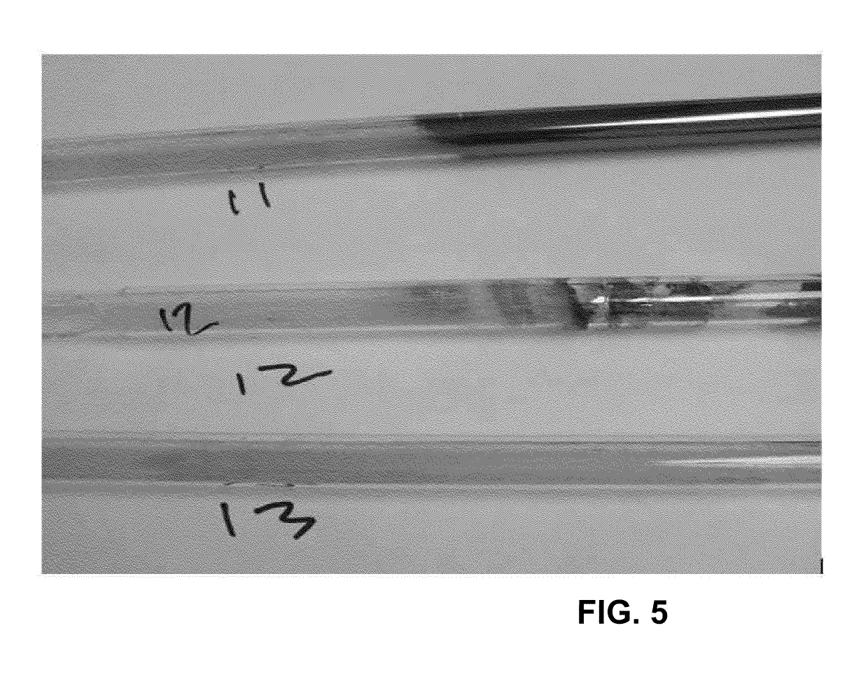

FIG. 3 shows a more complete diagram than FIG. 2 because FIG. 3 shows heating lines as well. FIG. 4 is a photograph of an apparatus demonstrating an embodiment of the present invention. FIG. 5 shows three tubes that were used during runs, conducted in accordance with some embodiments of the invention at various temperatures and residence times, and had silicon deposited on the inner wall of the tubes. Table 1 summarizes the characteristics of the runs of some embodiments of the invention.

In some embodiments, one of the key conditions was found to be the temperature of the furnace (201, 301). In some embodiments, another key condition was the residence time. In some embodiments, the apparatus, specifically bubbler (203, 303) and silicon samples in the quartz tube reactor, had to be purged free of all oxygen, by running argon through them. In some embodiments, traces of oxygen resulted in a formation of silicon dioxide at the furnace exhaust when TCS was introduced.

In some embodiments, the bubbler (203, 303) had with the TCS in it. In some embodiments, improved results were obtained when the bottom half of the bubbler (203, 303) was set in a water bath 307 at 30 degrees C. In some embodiments, lines and the top half of the bubbler (203, 303) were also heated with tubing 308 in contact with the lines carrying water from a circulating bath of water at 50 degrees C. to prevent condensation in the lines. In some embodiments, a typical gas flow from the bubbler (203, 303) to the tube in the furnace was approximately 80-90% TCS vapor in argon(the TCS vapor with a TCS concentration of about 80-90% of its total volume, measured by argon gas flow meter and weight loss of the bubbler). In some embodiments, a trap 304 is filled with 10% sodium hydroxide. In some embodiments, another data point was the residence time of the TCS in a given run at a particular reactor (tube) temperature. This data point was determined by knowing the amount of TCS being used per minute, the argon flow, and the reaction temperature and void volume. The void volume is a volume of the reactor that is not occupied by the silicon particles. The residence time is the void volume divided by total gas flow (e.g. TCS plus argon) at a reaction temperature.

TABLE 1

| | Temp | Run time | | Si size | Si wt | V_{tube total} | V_{Silicon} | V_{void} |
|---|---|---|---|---|---|---|---|---|
| Run # | ° C. | hour | | microns | gm | cc | cc | cc |
| 2 | 750° C. | 1 | hour | | 0 | 47.85 | 0 | 47.85 |
| 3 | 764° C. | 4.5 | hours | 1200-2000 | 32.05 | 47.85 | 13.75 | 34.15 |
| 4 | 650° C. | 5.5 | hours | 1200-2000 | 63.54 | 47.85 | 27.27 | 20.58 |
| 5 | 750° C. | 5 | hours | 1200-2000 | 64.75 | 47.85 | 27.79 | 20.06 |
| 6 | 700° C. | 5.25 | hours | 1200-2000 | 66.39 | 47.85 | 28.49 | 19.36 |
| 7 | 750° C. | 5.75 | hours | 1200-2000 | 64.11 | 47.85 | 27.51 | 20.34 |
| 8 | 800° C. | 4.2 | hours | 800-1200 | 68.01 | 47.85 | 29.19 | 18.66 |
| 9 | 750° C. | 3 | hours | 600-1000 | 69.07 | 47.85 | 29.64 | 18.21 |
| 10 | 780° C. | 3 | hours | 600-1000 | 69.81 | 47.85 | 29.96 | 17.89 |
| 11 | 780° C. | 2.33 | hours | 600-1000 | 72.79 | 47.85 | 31.24 | 16.61 |
| 12 | 780° C. | 2.5 | hours | 2000-4000 | 61.73 | 47.85 | 26.49 | 21.36 |
| 13 | 780° C. | 2.5 | hours | 600-1000 | 63.62 | 47.85 | 27.30 | 20.55 |
| 14 | 770° C. | 6 | hours | 1400-2000 | 300 | 186.05 | 128.75 | 57.30 |
| 15 | 770° C. | 3.8 | hours | 1400-2000 | 283 | 186.05 | 121.46 | 64.59 |

| | | Δ Empty tube | | | | | |
|---|---|---|---|---|---|---|---|
| | Δ Full tube | or wt of coating | Wt_{deposit on Silicon} | Wt_{powder} | Ar Flow rate | TCS flow rate | Residence time |
| Run # | gm | gm | gm | gm | cc/min | gm/min | sec |
| 2 | 1.33 | 0.82 | | 0.51 | 125 | 1.3 | 1.56 |
| 3 | 3.98 | 2.06 | 1.92 | 0 | 55 | 0.63 | 2.19 |
| 4 | 0.41 | 0 | 0.41 | 0 | 27 | 0.45 | 2.31 |
| 5 | 1.65 | 0.18 | 1.44 | 0 | 11 | 0.19 | 4.93 |
| 6 | 0.79 | 0.17 | 0.62 | 0 | 35 | 0.45 | 1.96 |
| 7 | 0.01 | 0.05 | 0 | 0 | 35 | 0 | 6.4 |
| 8 | 6.05 | — | — | — | 67 | 0.67 | 1.06 |
| 9 | 1.92 | 0.15 | 1.77 | 0 | 90 | 1.03 | 0.74 |
| 10 | 3.08 | 0.11 | 2.97 | 0 | 60 | 0.62 | 1.13 |
| 11 | 3.29 | 2.26 | 1.03 | 0 | 47 | 1.36 | 0.62 |
| 12 | 2.85 | 0.47 | 2.39 | 0 | 35 | 1.81 | 0.64 |
| 13 | 2.67 | 0.15 | 2.52 | 0 | 25 | 0.56 | 1.77 |
| 14 | 17 | — | 17 | 0 | 115 | 3.13 | 0.91 |
| 15 | 10 | 0 | 10 | 0 | 65 | 2.1 | 1.56 |

Table 1 summarizes the conditions and results of 15 runs in accordance to some embodiments of the invention. Specifically, Table 1 identifies that according to some embodiments, the furnace temperature (reaction temperature) varies from 650 degrees Celsius to 850 degrees Celsius during 15 runs. Table 1 identifies that according to some embodiments, the total run time varied between 1 hour and 6 hours. According to some embodiments, run no. 1 may precede before any other run in order to prime a tube and expunge any resident air.

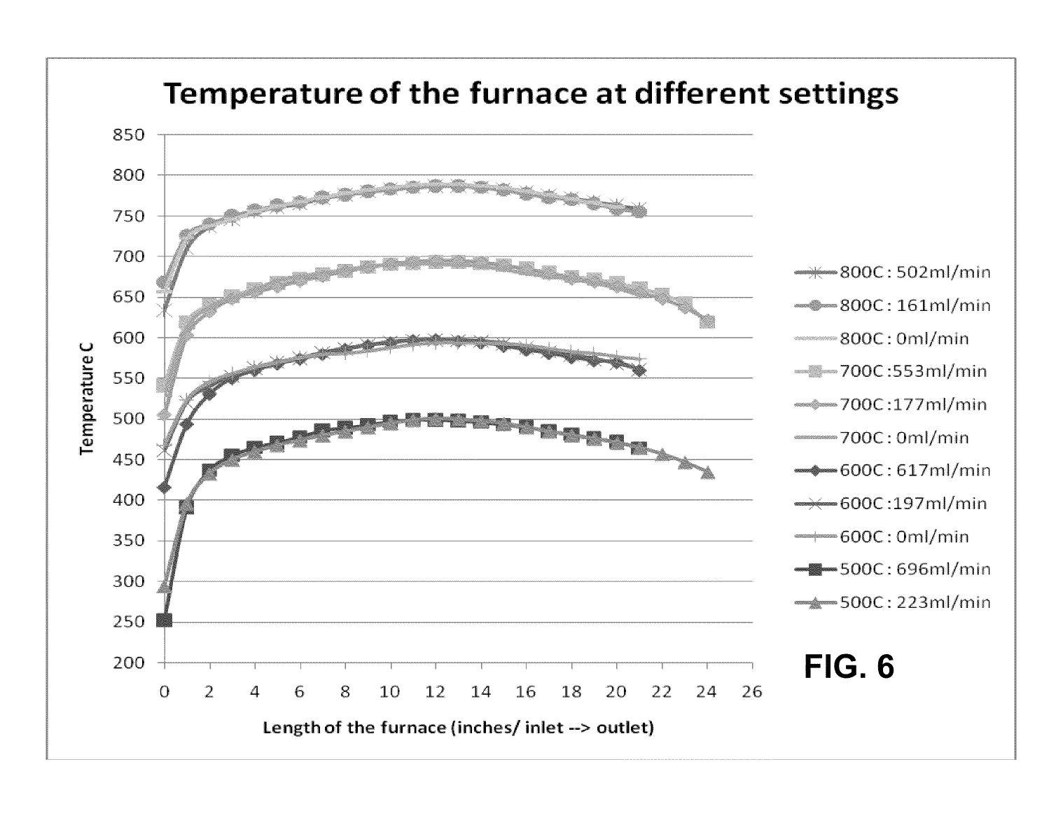

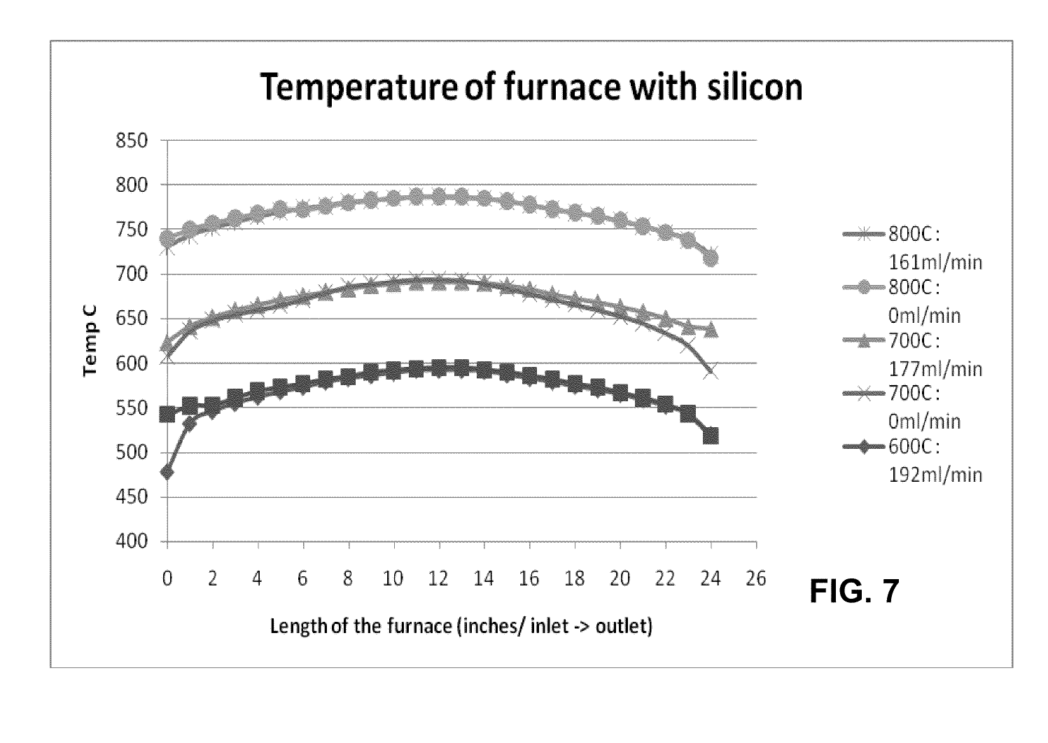

In some embodiments, the quartz reactor tubes were calibrated to determine temperature by heating them while the temperatures were measure along the length. FIG. 6 and FIG. 7 show diagrams of a distribution of temperature in tubes that were empty and filled with silicon particles such as in runs, summarized in Table 1. For example, FIG. 6 shows a temperature distribution of an empty 0.5 OD inch tube at different temperatures that varied from 500 to 800 degrees Celsius and at different rates of gas flow through the tube. In contrast, FIG. 7 shows a temperature distribution of a silicon packed 0.5 OD inch tube at different temperatures that varied from 600 to 800 degrees Celsius and at different rates of gas flow through the tube.

In another example, there was largely no difference in the temperature with and without the presence of the silicon particles in the tube. In some embodiments, the average temperature was determined by taking the average of the temperatures from the middle 15 inches of each tube (in the furnace hot zone).

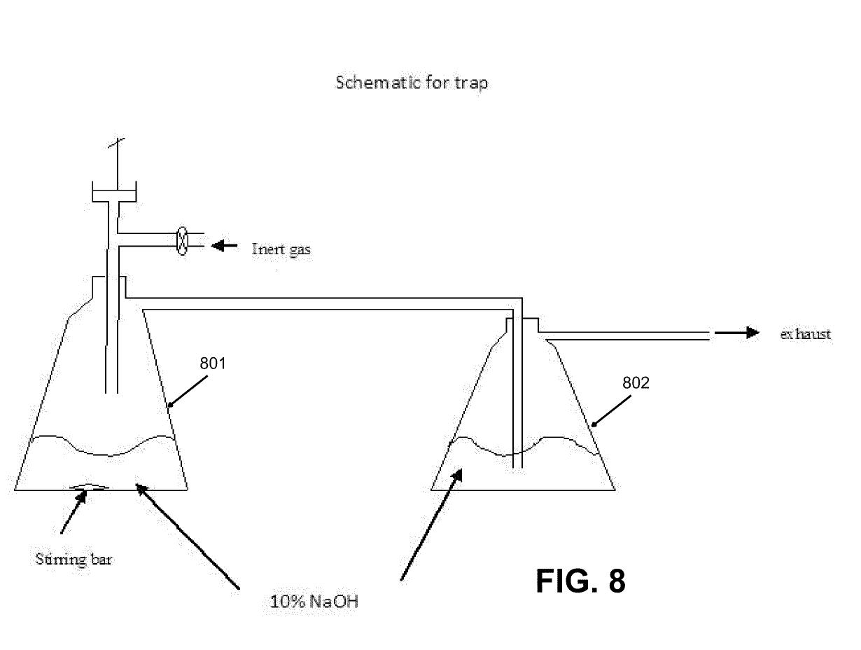

In some embodiments, the consideration was given to a manner that a gas stream coming out of tubes was handled. In some embodiments, a first approach, shown in FIG. 8 was to send the gas stream through caustic scrubbers (801, 802) filled with 10% sodium hydroxide. In some embodiments, hydrogen and argon passed through the scrubbers (801, 802), and TCS and STC present in the reaction effluent were decomposed as follows:

2HSiCl₃+14NaOH→H₂+2(NaO)₄Si+6NaCl+6H₂O (6)

SiCl₄+8NaOH→(NaO)₄Si+4NaCl+4H₂O (7)

In some embodiments, the first approach required a more frequent changing of the scrubbers (801, 802) and led to occasional plugging of lines due to orthosilicate ((NaO)₄Si) conversion to silicon dioxide (Si₂O) when the NaOH base was used up as follows:

(NaO)₄Si+SiCl₄→4NaCl+2SiO₂ (8)

Referring to FIG. 3, in some embodiments, a second approach, which may be preferred under certain conditions, consisted of placing a trap 304 in an ice bath 305 of 0 degrees Celsius before the scrubber 306 in order to remove sufficient amount of TCS and STC products as liquids. Accordingly, the trap 304 collected the sufficient amount of TCS and STC fractions present in a effluent gas that emerged from a reactor tube and let hydrogen and other gases to pass into the scrubber 306. In some embodiments, the trap 304 at 0 degrees Celsius collected a substantial portion of TCS (boiling point 31.9 degrees Celsius) and STC (boiling point 57.6 degrees Celsius) fractions present in the effluent gas.

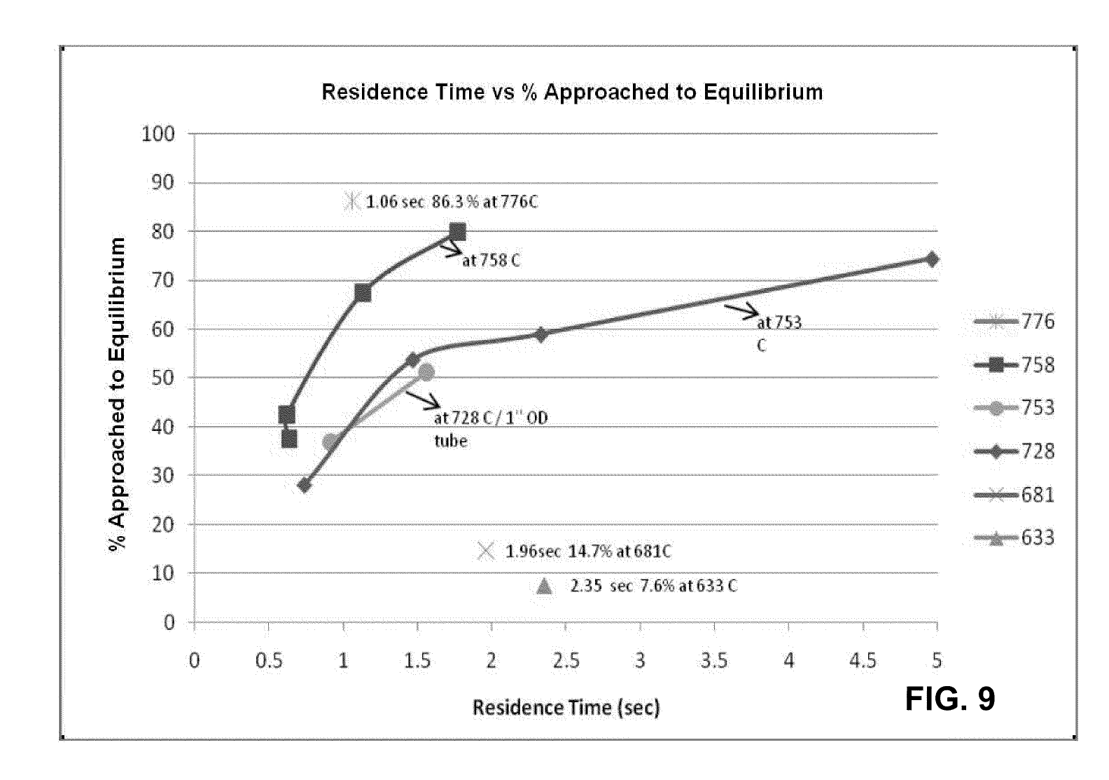

FIG. 9 shows a chart representing a summary of exemplary conditions and results from some of runs 1-15, whose data is summarized in Table 2. Table 2 is based on the raw data about each run's conditions and results provided in Table 1. Specifically, FIG. 9 and Table 2 summarize the conditions and results for runs for some embodiments in which a reactor tube was filled with a static bed of granular seeds silicon. For example, FIG. 9 shows a relationship between residence time and a percent (%) approached to the theoretical equilibrium, as further explained. For some embodiments, as shown in FIG. 9 and Table 2, temperatures in a range of 550-800 degrees Celsius resulted in sufficiently desirable rates of TCS deposition (the reaction (1)). FIG. 9 and Table 2 are also based on some selected embodiments of the present invention that would have a residence time condition in a range of 0.6 to 5 seconds. In some embodiments, the preceding range of residence times is applicable to the operation of a fluidized bed reactor.

For some embodiments, as shown in FIG. 9 and Table 2, runs were made with a wide range of silicon particles of difference sizes (600 to 4000 micron diameters) or even no silicon at all (Run # 2). As shown in FIG. 9 and Table 2, a number of reaction data points about some embodiments were recorded. For example, a quartz reactor tube was weighed, and then the tube was filled with 24 inches of granular silicon. Then, based on the weight of initial silicon added and a known volume of the reactor tube it was possible to determine a void volume of the reactor tube given the known density of silicon (2.33 grams per cubic centimeter (gm/cc)). In some embodiments, amount of TCS used during the decomposition reaction was determined, for example, by weighing the bubbler 203 (FIG. 3) before and after a particular run. In some embodiments, the amount of product TCS and STC was obtained, for example, by weighing the trap 204 (FIG. 3) before and after a particular run. In some embodiments, one data point was a mass of silicon deposited from the decomposition reaction (1):

4HSiCl₃→Si+2H₂+3SiCl₄ (1)

In some embodiments, the mass of silicon deposited from the decomposition reaction (1) was obtained by, for example, weighing the quartz reactor tube before and after each run which provided the difference that was the amount of polysilicon deposited in the tube during a particular run. In some embodiments, another data point was a ratio of Si (deposited)/TCS (consumed) (Si/TCS). For example, the ratio of Si (deposited)/TCS (consumed) measured how far the TCS decomposition reaction (1) progressed. If the TCS decomposition reaction progressed to 100% completion then the Si/TCS theoretical ratio is 0.0517 (a ratio of the molecular mass of silicon (Mw=28) to the molecular mass of four moles of TCS (Mw=4×135.5=542)). Since the TCS decomposition reaction (1) is an equilibrium reaction, it will not go to the 100% completion. In a chemical process, an equilibrium is the state in which the chemical activities or concentrations of the reactants and products have no net change over time. Usually, this would be the state that results when the forward chemical process proceeds at the same rate as their reverse reaction. The reaction rates of the forward and reverse reactions are generally not zero but, being equal, there are no net changes in any of the reactant or product concentrations. The equilibrium Si/TCS ratio was based on ASPEN Process Simulator calculations of the equilibrium constant and was a function of a reactor tube's temperature. The ASPEN Process Simulator by Aspen Technology, Inc is a computer program that allows the user to simulate a variety of chemical processes. ASPEN does mass and energy balances and has information about thermodynamic properties for a variety of industrially important pure fluids and mixtures stored in its data bank.

For some embodiments, the calculated equilibrium Si/TCS ratio was in a range of 0.037-0.041. In some embodiments, from knowing the equilibrium Si/TCS ratio and the observed Si/TCS ratio, it was possible to determine the percent approached to equilibrium of the TCS decomposition reaction (1) in a particular reactor tube.

In some embodiments, the conversion of TCS was determined as a percent of the approached to equilibrium conversion. In some embodiments, as FIG. 9 and Table 2 show, temperatures of 750-780 C are sufficient to achieve more than 50% of the equilibrium conversion of TCS to Si at a residence time of 1.5 second or less. In one example, at 776 degrees Celsius, the TCS approached to equilibrium was greater than 85% even at a residence time of 1 second. In another example, at temperatures of 633-681 degrees Celsius and residence times of 2 to 2.5 seconds, there was only an insubstantial amount of silicon deposition.

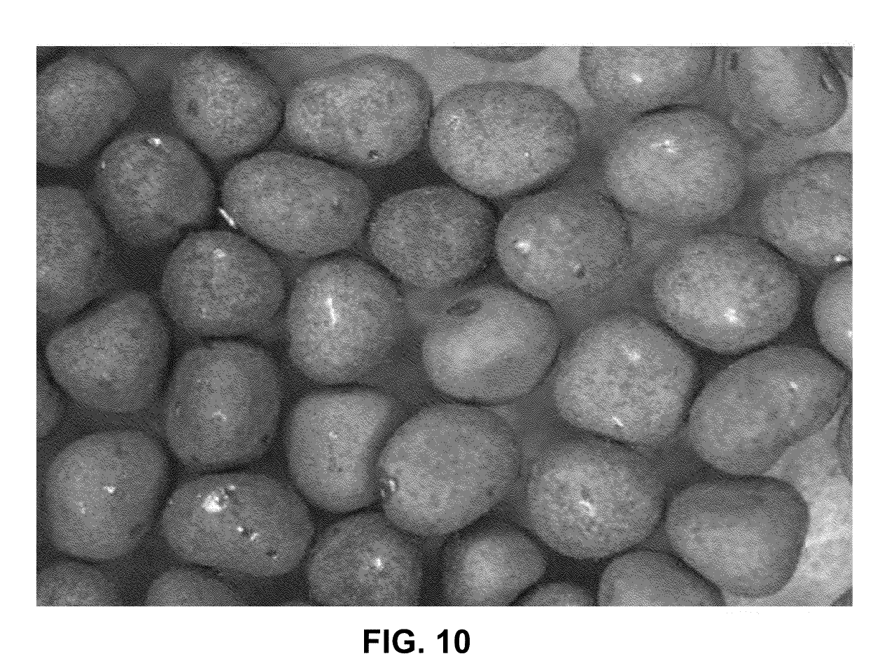

Consequently, as FIG. 10 and Table 2 show, for some embodiments, a rate of silicon deposition is sufficiently independent from a surface area of silicon particles in a reaction tube, which conforms with a prediction based on the TCS decomposition mechanism.

TABLE 2

| | | | Si Produced/ | | | |
|---|---|---|---|---|---|---|
| | Reaction Temp | Si Produced/ | TCS feed | % Approached | Residence | Si Size |
| Run # | ° C. | TCS feed | (at Equilibrium) | To Equilibrium | time (sec) | (microns) |
| 2 | 728 | 0.021 | 0.039 | 53.80% | 1.47 | empty tube/ |
| | | | | | | no Silicon |
| 3 | 728 | 0.023 | 0.039 | 59.00% | 2.23 | 1200-2000 |
| 4 | 633 | 0.0028 | 0.037 | 7.60% | 2.35 | 1200-2000 |
| 5 | 728 | 0.029 | 0.039 | 74.40% | 4.96 | 1200-2000 |
| 6 | 681 | 0.0056 | 0.038 | 14.70% | 1.96 | 1200-2000 |
| 8 | 776 | 0.035 | 0.041 | 86.30% | 1.06 | 800-1200 |
| 9 | 728 | 0.011 | 0.039 | 28.20% | 0.74 | 600-1000 |
| 10 | 758 | 0.027 | 0.040 | 67.50% | 1.13 | 600-1000 |
| 11 | 758 | 0.017 | 0.040 | 42.50% | 0.62 | 600-1000 |
| 12 | 758 | 0.015 | 0.040 | 37.50% | 0.64 | 2000-4000 |
| 13 | 758 | 0.032 | 0.040 | 80.00% | 1.77 | 600-1000 |
| 14 | 753 | 0.015 | 0.040 | 37.50% | 0.906 | 1400-2000 |
| 15 | 753 | 0.015 | 0.040 | 51.22% | 1.56 | 1400-2000 |

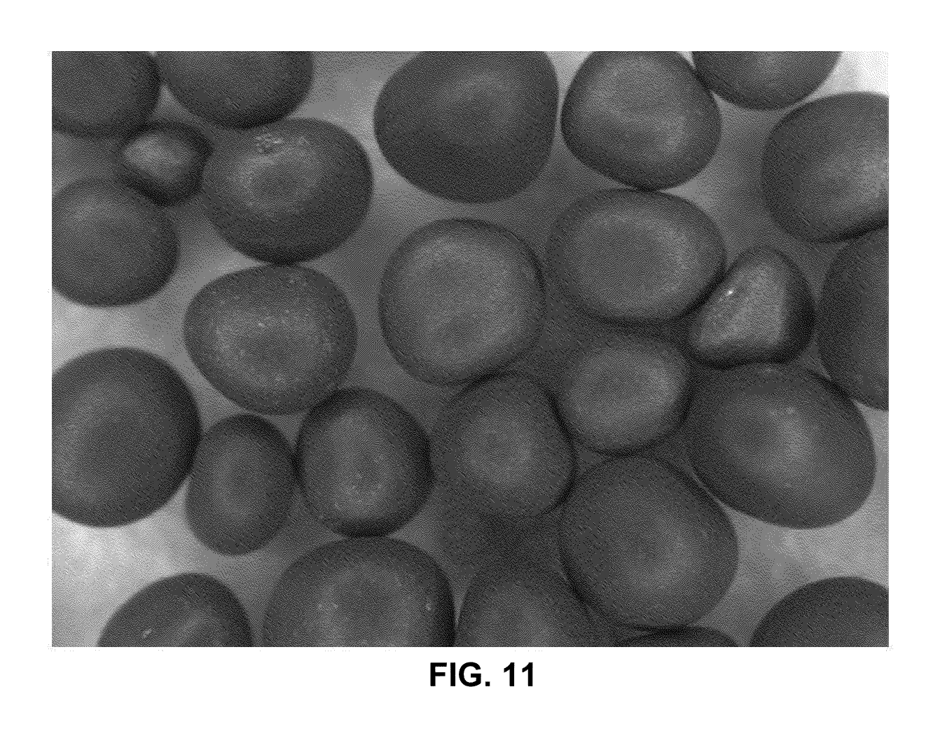

FIG. 10 depicts an example of silicon particles with a coating of deposited silicon from the TCS decomposition that took place in accordance with some embodiments of the present invention. FIG. 11 depicts an example of original silicon seed particles utilized in some embodiments of the present invention to fill the reactor tubes prior to the deposition.

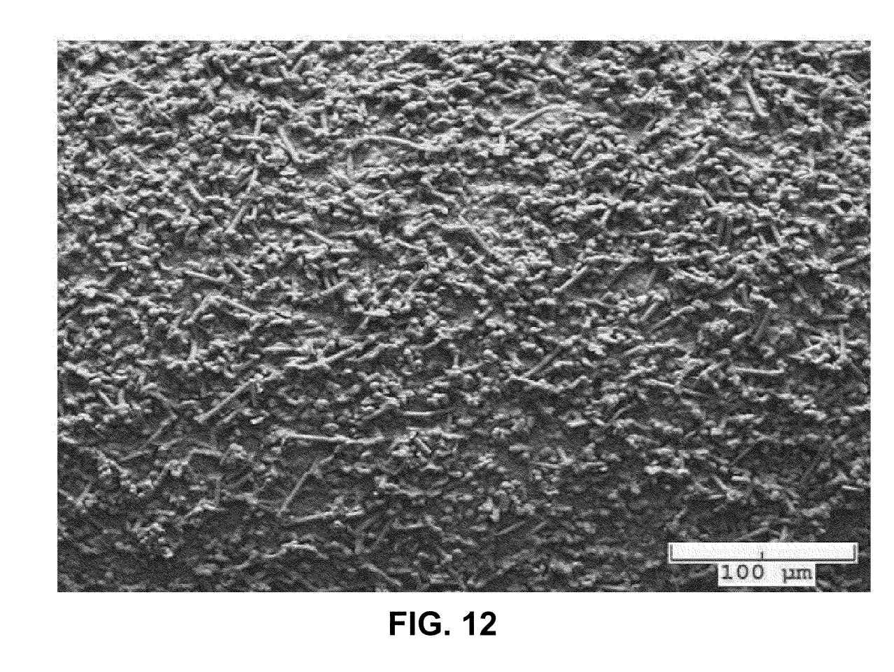

Samples of silicon coated seed silicon particles grown in the fixed bed reactor tubes according to some embodiments of the invention, including samples that were produced during the exemplary runs (fixed bed reactor tubes) identified in Table 2, were examined by using a scanning electron microscope (SEM). For example, FIG. 12 shows a SEM photograph of an example of a surface of a silicon particle coated with deposed silicon in accordance with some embodiments of the present invention. In FIG. 12, the growth of silicon crystallites was observed on the surface of the particle.

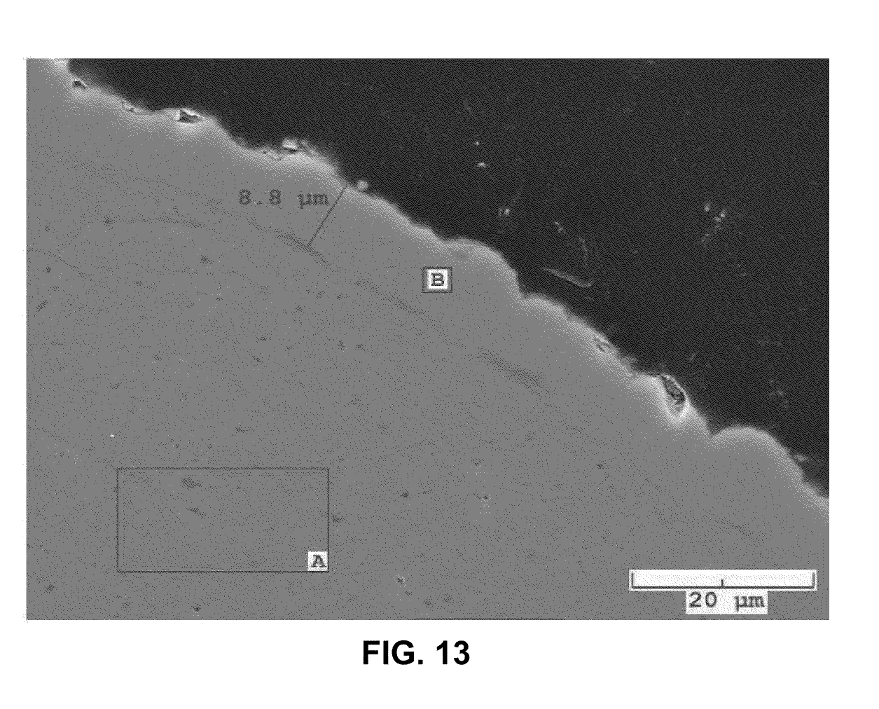

FIG. 13 shows a SEM photograph of a cross-section of a silicon particle coated with deposited silicon in accordance with some embodiments of the present invention. In FIG. 13, starting seed silicon material (the silicon particle, identified with “A”) is coated with a solid layer of silicon (the deposited layer, identified with “B”) formed by chemical vapor deposition upon the TCS decomposition. The thickness of the deposited layer is 8.8 microns (μm). It is noted that in some embodiments, the resulted silicon coating may have higher density than the more porous core of the original seed particle. In some embodiments, in the fluidized bed reactor, the thickness of the deposited layer may depend on at least a residence time of polysilicon seeds in the reactor, and/or rate of deposition, and/or size of polysilicon seeds.

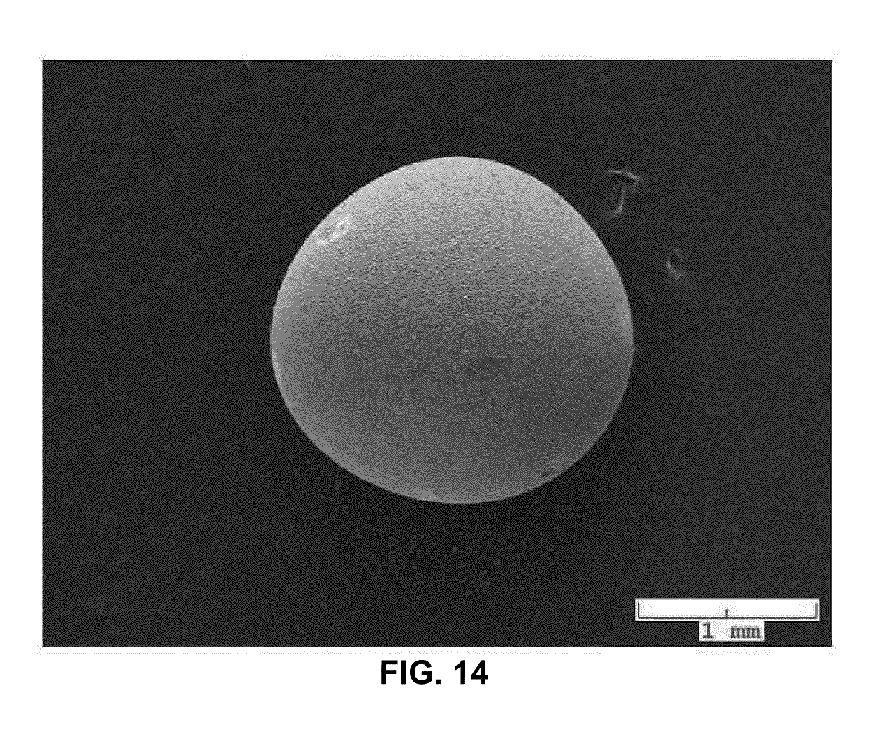

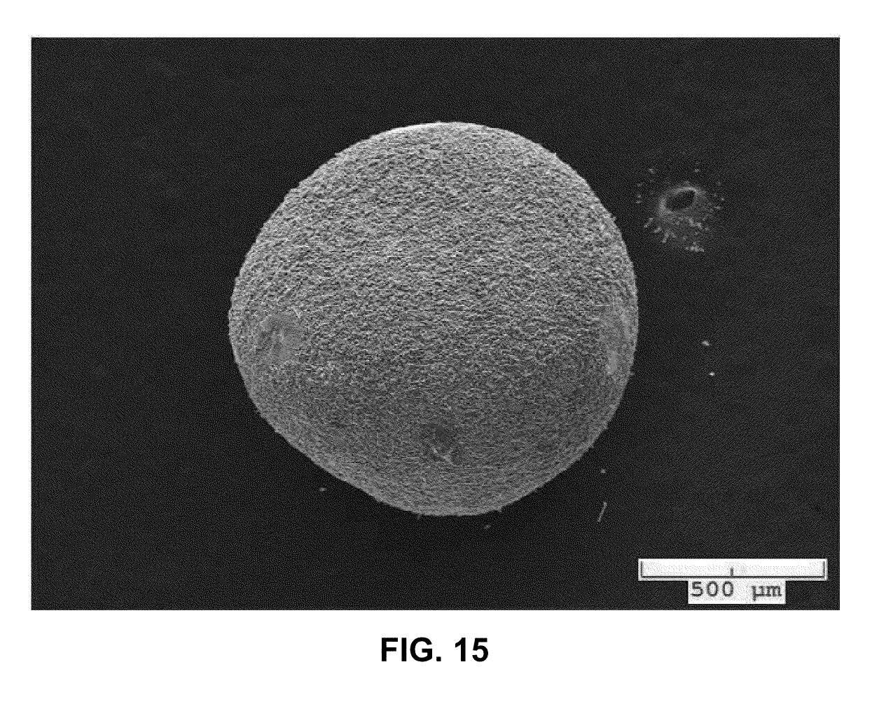

FIG. 14 shows a SEM photograph of a silicon particle that was lightly coated with the deposited silicon in accordance with some embodiments of the present invention. FIG. 15 shows a SEM photograph of a silicon particle in accordance with some embodiments of the present invention that was more heavily coated with the deposited silicon formed from the TCS decomposition than the particle in FIG. 14. In some embodiments, in the fluidized bed reactor, the polysilicon seeds are uniformly coated. In some embodiments, in the fluidized bed reactor, as the polysilicon seeds grow, their shape may become spherical.

In some embodiment, at the start of the deposition process, there was a formation of a relatively smooth coating of silicon on a surface of seed particles, as shown in FIG. 14. Later, microcrystals of silicon material, as in FIG. 12, could form on the surface of the seed particles, especially in some embodiments that utilized the fixed bed reactor tubes. In some embodiments, the conditions of the TCS decomposition reaction and a particular fluidized bed reactor are adapted to favor the formation of a silicon layer and to sufficiently minimize the formation/growth of microcrystallites on the surface of the silicon particles.

In some embodiments utilizing a fluidize bed process, the resulted coated silicon particles have a surface which is smoother than a surface of coated particles produced in the fix bed process.

Some embodiments of the present invention demonstrated that the TCS decomposition process that was conducted in accordance with the present invention is sufficiently scalable to varous types and shapes of reactors, including but not limiting to fluidized bed reactors. For example, referring back to FIG. 9, Table 1 and Table 2, runs #14 and #15 were conducted using a 1.0 inch OD quartz reactor tube. Accordingly, embodiments of runs #14 and #15 represent a scale up of about 5 fold over some embodiments that used 0.5 inch OD quartz tube. For example, as Table 1 shows, the total volume of the one inch tube used in the embodiment of run #14 was 186.05 cubic centimeters (cc); in contrast, the total volume of the 0.5 inch tube used in embodiments of runs #1-13 was 47.85 cc. Some embodiments corresponding to runs #14 and #15 demonstrated sufficient deposition rates at 753 degrees Celsius with the residence times of 1.45 sec. and 2.5 sec. As Table 1 and Table 2 show, the results of runs #14 and #15 were consistent with runs of another embodiments that utilized the 0.5 inch tubes. The consistent data speaks of scalability of some embodiments of the present invention. In some embodiments, the TCS enriched gas was passed through reactor tubes without the initial seed particles. In some embodiments, the TCS enriched gas was passed (typically for two hours) through the empty reactor tubes at various temperatures between 500 and 700 degrees Celsius with residence times between 1 and 5 seconds. In some embodiments, at certain conditions, TCS could be heated and transported in tubes or reactors without depositing silicon.

Table 3 shows the results from some embodiments of runs under different conditions and amount of silicon deposited in a particular tube. The data of Table 3 shows relationships that specify, based on, for example, a temperature and/or a residence time, how some embodiments may include heating a stream of TCS vapor (e.g. using a heat exchanger) without depositing silicon.

As detailed above, in some embodiments, rates of the silicon deposition from TCS would be sufficiently similar for packed or empty reactors and would typically depend on a given set of conditions (e.g. TCS concentration, reaction temperature, residence time, etc). In some embodiments, the deposited silicon may be in a form of amorphous powder, if no suitable substrate is present (for example, an empty or free space reactor). In some embodiments, in the presence of a suitable substrate (e.g. silicon seed particles), there is a preferential tendency to deposit (e.g. chemical vapor deposition) on the substrate to form a silicon coating instead of silicon powder. In some embodiments, by varying temperatures and residence times, polysilicon is continuously deposited on the silicon seed particles in a 0.5 inch tube.

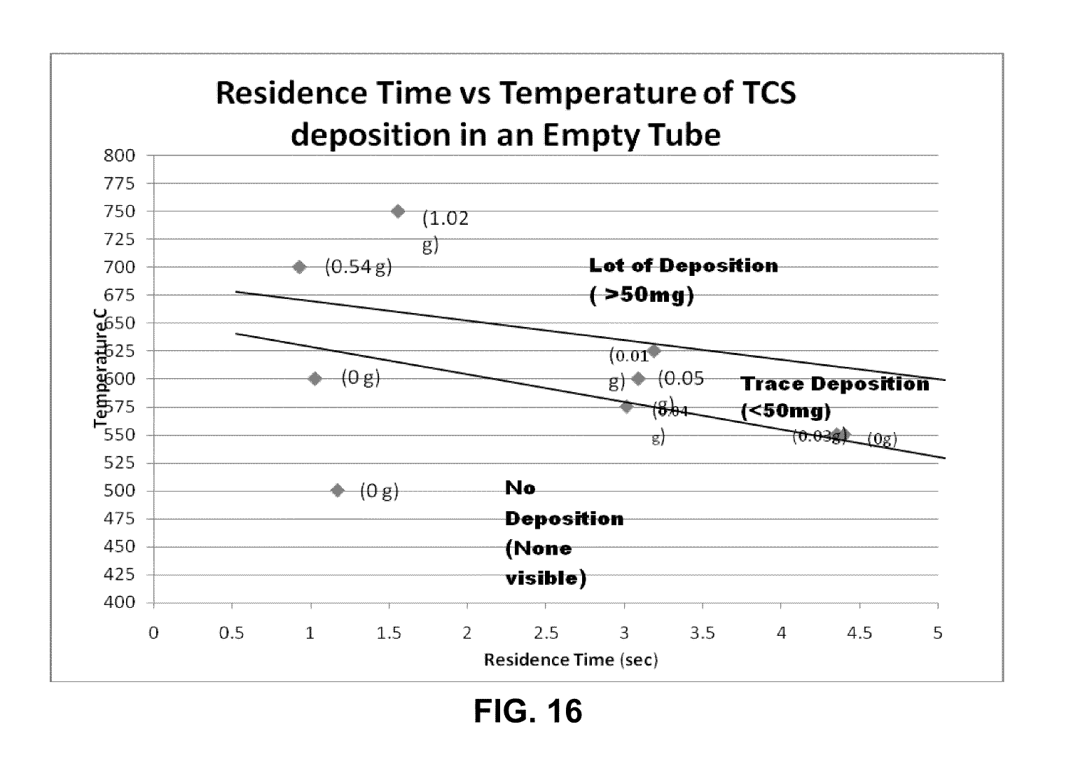

FIG. 16 depicts a graph representing results produced by some embodiments of the present invention. FIG. 16 is based on data provided in Table 3. As shown by Table 3 and FIG. 16, in some embodiments, there is no deposition at certain lower temperatures. As shown by Table 3 and FIG. 16, in some embodiments, at certain intermediate temperatures there is a fine coating of silicon (less than 50 mg) on a quartz tube. As shown by Table 3 and FIG. 16, in some embodiments, at higher temperatures (above approximately 675 degrees Celsius) there is an increased deposition of silicon at residence times above approximately 1 second. In some embodiments, longer residence times produce more deposition.

In one embodiment, the TCS decomposition may be conducted in an empty “free space” reactor. In one embodiment, the TCS decomposition in a reaction zone of the empty reactor can substantially achieve theoretical equilibrium at the residence time of 2 seconds and a temperature of 875 degrees Celsius. In this embodiment, the resulted product will be predominately amorphous silicon powder. In one embodiment, the TCS decomposition may be conducted in a fluidized bed reactor, having silicon seed particles suspended within the reaction zone (i.e. presence of a suitable substrate in the reaction zone). In one embodiment, at the residence time of 2 seconds and at a temperature of 875 degrees Celsius in a reaction zone of a fluidized bed reactor, the TCS decomposition is completed or near completion when an effluent gas leaves the reaction zone and silicon seed particles are coated with silicon.

In one embodiment, when the effluent gas leaves the reaction zone having the TCS decomposition still proceeding (as in Table 2, run #15), to avoid the formation of the amorphous silicon powder, the effluent gas is quenched to a temperature at which the TCS decomposition process ceases or is at substantial equilibrium.

In one embodiment, a method includes feeding at least one silicon source gas and polysilicon silicon seeds into a reaction zone; maintaining the at least one silicon source gas at a sufficient temperature and residence time within the reaction zone so that a reaction equilibrium of a thermal decomposition of the at least one silicon source gas is substantially reached within the reaction zone to produce an elemental silicon; wherein the decomposition of the at least one silicon source gas proceeds by the following chemical reaction: 4HSiCl₃←→Si+3SiCl₄+2H₂, wherein the sufficient temperature is a temperature range between about 600 degrees Celsius and about 1000 degrees Celsius; wherein the sufficient residence time is less than about 5 seconds, wherein the residence time is defined as a void volume divided by total gas flow at the sufficient temperature; and c) maintaining a sufficient amount of the polysilicon silicon seeds in the reaction zone so as to result in the elemental silicon being deposited onto the polysilicon silicon seeds to produce coated particles.

In one embodiment, the method of present invention includes simultaneous feeding at least one silicon source gas and polysilicon silicon seeds into a reaction zone of a fluidized bed reactor. In one embodiment, the method of present invention includes first feeding polysilicon silicon seeds into a reaction zone of a fluidized bed reactor, and then feeding at least one silicon source gas into the reaction zone. In one embodiment, the silicon source gas is used to fluidize polysilicon silicon seeds in the reaction zone. In one embodiment, the method of present invention includes feeding at least one silicon source gas into a reaction zone of a fluidized bed reactor, and then feeding polysilicon silicon seeds into the reaction zone.

In one embodiment, the sufficient heat is in a range of 700-900 degrees Celsius.

In one embodiment, the sufficient heat is in a range of 750-850 degrees Celsius.

In one embodiment, the silicon seeds have a distribution of sizes of 500-4000 micron.

In one embodiment, the silicon seeds have a distribution of sizes of 1000-2000 micron.

In one embodiment, the silicon seeds have a distribution of sizes of 100-600 micron.

In one embodiment, a method includes a) feeding at least one silicon source gas into a reaction zone; b) maintaining the at least one silicon source gas at a sufficient temperature and residence time within the reaction zone so that a reaction equilibrium of decomposition of the at least one silicon source gas is substantially reached within the reaction zone to produce an elemental silicon; i) wherein the decomposition of the at least one silicon source gas proceeds by the following chemical reaction: 4HSiCl₃←→Si+3SiCl₄+2H₂, ii) wherein the sufficient temperature is a temperature range between about 600 degrees Celsius and about 1000 degrees Celsius; iii) wherein the sufficient residence time is less than about 5 seconds, wherein the residence time is defined as a void volume divided by total gas flow at the sufficient temperature; and c) producing amorphous silicon.

In some embodiments, TCS may be supplied into a deposition reactor at: 1) a temperature of about 300-350 degrees Celsius, 2) a pressure of about 20-30 psig; and 3) a rate of 900-1050 lb/hr (pounds/hour); and residence time of about 0.5-5 seconds. In one embodiment, TCS may be supplied into a deposition reactor at: 1) a temperature of about 300-350 degrees Celsius, 2) a pressure of about 20-30 psig; and 3) a rate of 900-1050 lb/hr (pounds/hour); and residence time of about 1-2 seconds. In some embodiments, the deposition reactor's internal temperature in a reaction zone may be about 750-850 degrees Celsius. In one embodiment, the resulted effluent gas has the following characteristics: 1) a temperature of about 850-900 degrees Celsius, 2) a pressure of about 5-15 psig; and 3) a rate of TCS—210-270 lb/hr and a rate of STC—650-750 lb/hr.

TABLE 3

| | | | | | | | TCS | | | | |
|---|---|---|---|---|---|---|---|---|---|---|---|
| | | | Run | Tube | Tube | Wt Si | Total | Si | TCS feed | Argon | |
| | | | time | ID | Vol | Produced | Feed | Produced/ | rate | Flow | Residence |
| Run | Date | Temp ° C. | (min) | (mm) | (cc) | (gm) | (gm) | TCS feed | (gm/min) | (cc/min) | Time (sec) |
| 1 | Oct. 22, 2009 | 488 | 120 | 10 | 36 | 0 | 277 | 0 | 2.31 | 29 | 1.17 |
| 2 | Oct. 22, 2009 | 585 | 120 | 10 | 36 | 0 | 277 | 0 | 2.31 | 29 | 1.03 |
| 3 | Oct. 22, 2009 | 681 | 120 | 10 | 36 | 0.54 | 277 | 0.0019 | 2.31 | 29 | 0.93 |
| 4 | Oct. 23, 2009 | 610 | 120 | 10 | 36 | 0.05 | 92.6 | 0.0005 | 0.77 | 10 | 3.01 |
| 5 | Oct. 23, 2009 | 585 | 120 | 10 | 36 | 0.01 | 92.6 | 0.0001 | 0.77 | 10 | 3.09 |
| 6 | Oct. 23, 2009 | 560 | 120 | 10 | 36 | 0.04 | 92.6 | 0.0004 | 0.77 | 10 | 3.19 |
| 7 | Oct. 29, 2009 | 537 | 120 | 10 | 36 | 0.03 | 113 | 0.0003 | 0.94 | 10 | 2.72 |
| 8 | Oct. 29, 2009 | 537 | 120 | 10 | 36 | 0 | 109 | 0 | 0.91 | 14 | 2.75 |

In some embodiments, TCS may be supplied into a deposition reactor at: 1) a temperature of about 300-400 degrees Celsius, 2) a pressure of about 25-45 psig; and 3) a rate of 600-1200 lb/hr. In some embodiments, TCS may be supplied into a deposition reactor at: 1) a temperature of about 300-400 degrees Celsius, 2) a pressure of about 5-45 psig; and 3) a rate of 750-900 lb/hr. In some embodiments, TCS may be supplied into a deposition reactor at: 1) a temperature of about 300-400 degrees Celsius, 2) a pressure of about 5-45 psig; and 3) a rate of 750-1500 lb/hr.

In some embodiment, the deposition reactor's internal temperature in a reaction zone may be about 670-800 degrees Celsius. In some embodiments, the deposition reactor's internal temperature in a reaction zone may be about 725-800 degrees Celsius. In some embodiments, the deposition reactor's internal temperature in a reaction zone may be about 800-975 degrees Celsius. In some embodiments, the deposition reactor's internal temperature in a reaction zone was about 800-900 degrees Celsius.

In some embodiments, when a distribution of polysilicon seed particles varies from 100-600 micron, having a mean size of 300 micron, the TCS is supplied at a rate of 500 lb/hr. In another embodiments, when a distribution of polysilicon seed particles varies from 200-1200 micron, having a mean size of 800 micron, the TCS is supplied at a rate of 1000 lb/hr.

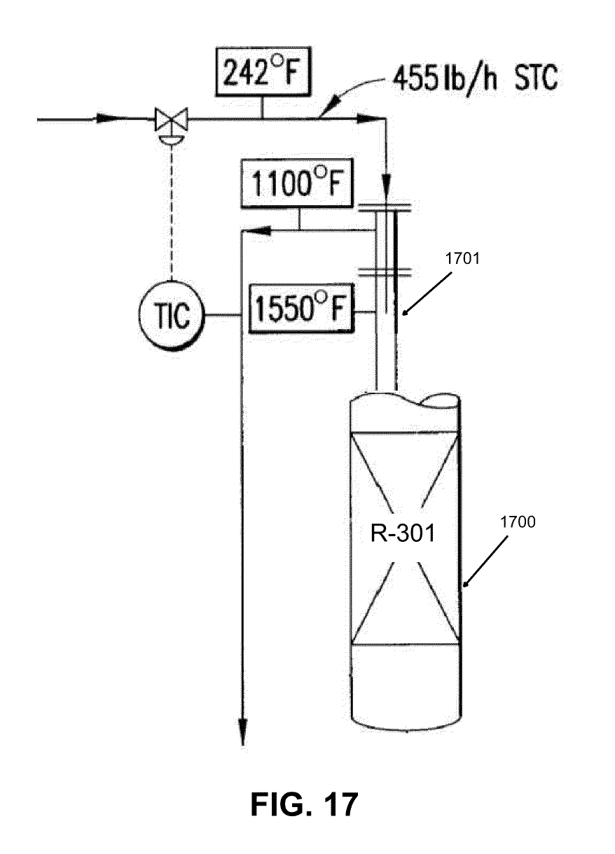

FIG. 17 shows a schematic diagram of an embodiment of the present invention. In one embodiment, the TCS deposition reaction takes place in a reactor 1700. The reaction temperature is about 1550° F. (or about 843 degrees Celsius). The concentration of supplied TCS is about 1000-1100 lb/hr because it takes about 450 lb/hr of STC at the temperature of about 242° F. (or about 117 degrees Celsius) to cool the resulting reaction gas to about 1100° F. (or about 593 degrees Celsius) in the pipe 1701.

In some embodiments, as detailed above, the TCS decomposition reaction (1) is a first order reaction and depends on the reaction temperature and the concentration of TCS. In some embodiments, as detailed above, a temperature of greater than 750 degrees Celsius may be needed and/or a residence time of around 1.6 seconds may be needed to achieve greater than 75% approached to the theoretical equilibrium of the TCS thermal decomposition. In some embodiments, as detailed above, in the presence of silicon seed material substrate, TCS reacts by chemical vapor deposition to place a layer of silicon on the seed silicon material.

While a number of embodiments of the present invention have been described, it is understood that these embodiments are illustrative only, and not restrictive, and that many modifications and/or alternative embodiments may become apparent to those of ordinary skill in the art. For example, any steps may be performed in any desired order (and any desired steps may be added and/or any desired steps may be deleted). For example, in some embodiments, seed particles may not be made totally from silicon, or may not contain any silicon at all. Therefore, it will be understood that the appended claims are intended to cover all such modifications and embodiments that come within the spirit and scope of the present invention.

We claim:

1. A method, comprising
a) feeding at least one silicon source gas and polysilicon silicon seeds into a reaction zone;
b) maintaining the at least one silicon source gas at a sufficient temperature and residence time within the reaction zone so that a reaction equilibrium of a thermal decomposition of the at least one silicon source gas is substantially reached within the reaction zone to produce an elemental silicon;
i) wherein the decomposition of the at least one silicon source gas proceeds by the following chemical reaction:
4HSiCl₃ [symbol] Si+3SiCl₄+2H₂
ii) wherein the sufficient temperature is a temperature range between about 700 degrees Celsius and about 1000 degrees Celsius;
iii) wherein the sufficient residence time is less than about 5 seconds, wherein the residence time is defined as a void volume divided by total gas flow at the sufficient temperature; and
c) maintaining a sufficient amount of the polysilicon silicon seeds in the reaction zone so as to result in the elemental silicon being deposited onto the polysilicon silicon seeds to produce coated particles.

2. The method of claim 1, wherein sufficient temperature is in a range of between about 700 and about 900 degrees Celsius.

3. The method of claim 1, wherein sufficient heat is in a range of between about 750 and about 850 degrees Celsius.

4. The method of claim 1, wherein the silicon seeds have a size of 500-4000 micron.

5. The method of claim 4, wherein the silicon seeds have a size of 1000-2000 micron.

6. The method of claim 4, wherein the silicon seeds have a size of 100-600 micron.

7. A method, comprising
a) feeding at least one silicon source gas into a reaction zone;
b) maintaining the at least one silicon source gas at a sufficient temperature and residence time within the reaction zone so that a reaction equilibrium of decomposition of the at least one silicon source gas is substantially reached within the reaction zone to produce an elemental silicon;
i) wherein the decomposition of the at least one silicon source gas proceeds by the following chemical reaction:
4HSiCl₃→Si+3SiCl₄+2H₂
ii) wherein the sufficient temperature is a temperature range between about 700 degrees Celsius and about 1000 degrees Celsius;
iii) wherein the sufficient residence time is less than about 5 seconds, wherein the residence time is defined as a void volume divided by total gas flow at the sufficient temperature; and
c) producing amorphous silicon.

8. The method of claim 7, wherein sufficient temperature is in a range of between about 700 and about 900 degrees Celsius.

9. The method of claim 7, wherein sufficient heat is in a range of between about 750 and about 850 degrees Celsius.
